(19) United States
(12) Patent Application Publication
(10) Pub. No.: US 2004/0166448 A1
(43) Pub. Date: Aug. 26, 2004

(54) Method for shrinking the image of photoresist

(75) Inventors: Vencent Chang, Taipei City (TW); George Liu, Ping-Cheng City (TW); Chia-Chen Chen, Hsin-Chu City (TW); Benjamin Szu-Min Lin, (US); Cheng-Chung Chen, (US)

Correspondence Address: Harold L. Novick, NATH & ASSOCIATES PLLC, 6th Floor, 1030 15th Street, N.W., Washington, DC, 20005, US

(73) Assignee: United Microelectronics Corp.

(21) Appl. No.: 10/717,603

(22) Filed: Nov. 21, 2003

Related U.S. Application Data
(63) Continuation-in-part of application No. 10/373,099, filed on Feb. 26, 2003.

(51) Int. Cl. G03F 7/40; G03F 7/26

(52) U.S. Cl. 430/324; 430/330

(57) ABSTRACT

First of all, a semiconductor substrate with a photoresist layer thereon is provided. Then a photoresist region is formed on the semiconductor substrate by a photolithography process. Next, a chemical reaction layer is formed within the photoresist region. Subsequently, a developing process is performed to remove the chemical reaction layer within the photoresist region to shrink the photoresist region in line width on the semiconductor substrate.

### CROSS-REFERENCE TO RELATED APPLICATIONS

This application is a continuation-in-part of co-pending application application Ser. No. 10/373,099 filed Feb. 26, 2003 and entitled “METHOD FOR SHRINKING PATTERN PHOTORESIST,” incorporated in its entirety herein by reference.

### BACKGROUND OF THE INVENTION

1. Field of the Invention

The present invention relates to a method for controlling the image of semiconductor process, and more particularly to a method for shrinking the image of the photoresist.

2. Description of the Prior Art

As semiconductor devices, such as the Metal-Oxide-Semiconductor device, become highly integrated the area occupied by the device shrinks, as well as the design rule. With advances in the semiconductor technology, the dimensions of the integrated circuit (IC) devices have shrunk to the deep sub-micron range. When the semiconductor device continuously shrinks in the deep sub-micron region, some problems described below are incurred due to the scaling down process. To enlarge the litho-window, the thickness of the photoresist layer has to be decreased. In the photolithography fabrication which transfers pattern on mask into photoresist, the step of development is used to develop the pattern in the photoresist which has been baked and exposed. Whereby, developer is used to partial of photoresist which does not correspond to any pattern, and then only partial photoresist which corresponds to the pattern is reserved. In general, after pattern on mask has been transferred into photoresist which located on surface layer, which locates on substrate, photoresist is divided into two parts: photoresist which corresponds to pattern, and photoresist which corresponds to nothing. In the Next step, developer is distributed, by the spray/puddle way or other ways, on photoresist to let every part of photoresist is covered by developer. Then, uses positive photoresist as example, the patterned photoresist is removed by developer and then only the photoresist being not patterned is reserved. Thus, the reserved photoresist could be used to define required pattern in underlying surface layer in following processes such as etch. Certainly, although shown example is positive photoresist, same action is appeared for negative photoresist.

The evolution of integrated circuits has evolved such that scaling down the device geometry is required. In the deep sub-micron technology of semiconductors, it's necessary that the line width of the photoresist is trimmed to be narrow, so as to obtain the semiconductor with the smaller dimensions. Conventional process for trimming the line width of the photoresist utilizes an etching process to shrink the critical dimension or the image of, after finishing the exposure and development process. In general, the etching process for shrinking photoresist is an isotropy etching process, and this process cannot trim the structure in profile of photoresist, so that the critical dimension or the image uniformity within the photoresist cannot be maintained. Additionally, another process is a trimming process with plasma that utilizes a plasma process with anisotropy electron beam to perform the etching process so as to shrink the photoresist. Regarding treating the photoresist with this process, its vertical etching rate will be larger than the horizontal etching rate thereof, so that top of the photoresist will be over lost when the predetermined critical dimension or the image thereof have not achieved yet, and thickness of the photoresist is over thin after trimming the line width to become the predetermined critical dimension or the image; and further, when the photoresist formed by the trimming process with plasma acts as an etching mask or an ion-implanting mask to perform the follow-up etching process or ion-implanting process, the gate oxide layer is usually etched thoroughly into the substrate at the main endpoint or the photoresist is easily punctured by ions. On the other hand, any conventional process for trimming the photoresist can not control the structure in profile, it is very difficult to avoid the problem of line edge roughness (LER), and all these prior arts have to proceed with the etching process in ex-situ environment, so that the process rate not only becomes be slow to prolong the process cycle time, but also the process cost will be increased.

However, controlling the critical dimension or the image is very important in the below deep sub-micron region. Especially, when the design rule is scaled down, the line width is reduced to be narrower, resulting in shrinkage of the photoresist more difficult to control or retain as critical dimension or the image requires. If the photoresist's profile can not be completely maintained, it will greatly affect the follow-up implanting process or etching process, and a possible shift in electricity will reduce the performance of the device. In accordance with the above description, a new and improved method for shrinking the critical dimension or the image of the photoresist is therefore necessary, so as to raise the yield and quality of the follow-up process.

### SUMMARY OF THE INVENTION

In accordance with the present invention, a method is provided that substantially overcomes the drawbacks of the above mentioned problems when shrinking the critical dimension or the image of photoresist by using existing conventional methods.

Accordingly, it is one objective of the present invention to provide a process for shrinking the photoresist. This invention utilizes a chemical reaction to form a chemical diffusion layer within the photoresist to control the chain reaction by way of the diffusive rate of the chemical material, so as to achieve the purpose for shrinking the photoresist. Furthermore, the present invention can control the profile of the reaction layer by way of the controlling the condition of a baking process to influence the critical dimension or the image of the photoresist, so the line width of that can be free biased. Moreover, this invention also can remove the chemical diffusion layer by way of using a developing process to form the photoresist with a line width smaller than the original line width. As disclosed as above, the process of the present invention for shrinking the photoresist can not only maintain the integrity profile of the photoresist but also avoid the problem of line edge roughness (LER). Therefore, the present invention can reduce the costs of the conventional process and hence correspond to economic effect, and that is appropriate for deep sub-micron technology when providing semiconductor devices.

It is a further objective of the present invention to provide a process for shrinking the photoresist in less processes because a developing process is reduced.

In accordance with the present invention, a method for shrinking the image of photoresist is disclosed. First of all, a semiconductor substrate with a photoresist layer thereon is provided. Then a photoresist region is formed on the semiconductor substrate by a photolithography process. Next, a chemical reaction layer is formed within the photoresist region. Subsequently, a developing process is performed to remove the chemical reaction layer to shrink the photoresist region in line width on the semiconductor substrate.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIGS. 1A-1E illustrate the cross-sectional views of the first embodiment for shrinking the image of photoresist of the present invention; and

FIGS. 2A-2E illustrate the cross-sectional views of the second embodiment for shrinking the image of photoresist of the present invention.

### DESCRIPTION OF THE PREFERRED EMBODIMENT

These preferred embodiments of the present invention are now described in greater detail. Nevertheless, it should be recognized that the present invention can be practiced in a wide range of other embodiments besides those explicitly described, and the scope of the present invention is expressly not limited except as specified in the accompanying claims.

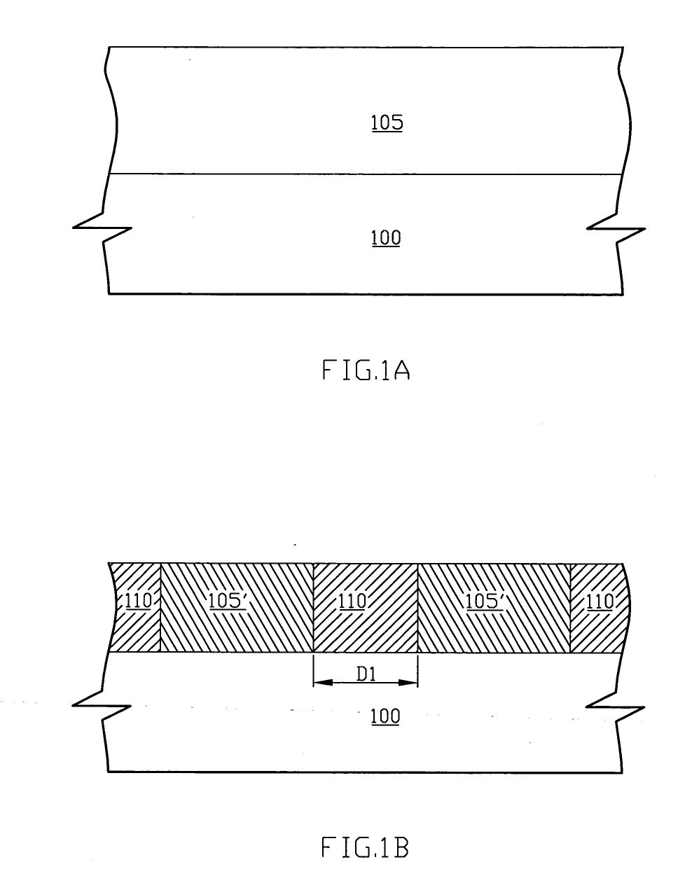

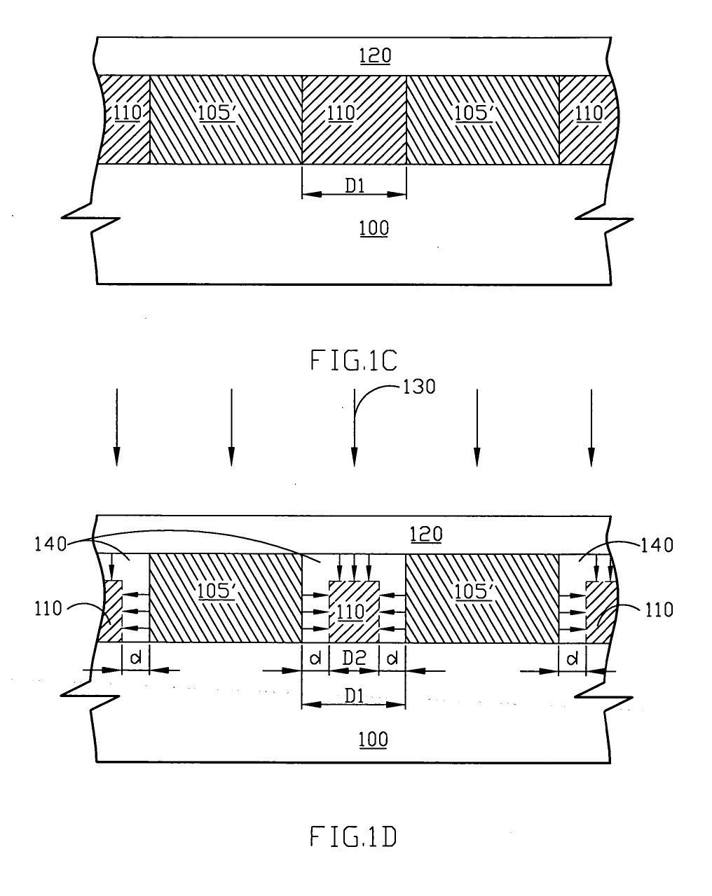

As illustrated in FIG. 1A, the first embodiment of the present invention provides a substrate 100, i.e. a semiconductor substrate, at first and then apply a photoresist layer 105 on the substrate 100. The photoresist layer 105 is exposed to form a nonirradiated region 110, i.e. a first photoresist region, with a first line width D1, i.e. an original line width, and an irradiated region 105′, i.e. a second photoresist region, including a first chemical material, as shown in FIG. 1B. Then a chemical diffusion layer 120, e.g. an acid-based layer or a fluorine-base acid, including a second chemical material is formed on the photoresist layer 105 comprising the nonirradiated region 110 and the irradiated region 105′, as shown in FIG. 1C. As shown in FIG. 1D, a baking process 130 is performed to diffuse the first chemical material within the irradiated region 105′ and the second chemical material within the chemical diffusion layer 120 into the nonirradiated region 110. Afterward, the material of the nonirradiated region 110 reacts with the first chemical material and the second chemical material to form a chemical reaction layer 140 being more solvable in developer with a diffusive depth d within the nonirradiated region 110. The diffusive depth d of the chemical reaction layer 140 within the nonirradiated region 110 depends on the diffusive rate of the first chemical material and the second chemical material. Subsequently, the chemical diffusion layer 120, the irradiated region 105′ and the chemical reaction layer 140 is removed by developer in a developing process 150 to form a second line width D2, i.e. a shrinking line width, of the nonirradiated region 110 on the substrate 100, as shown in FIG. 1E. The difference between the first line width D1 and the second line width D2 is the diffusive depth d of the chemical reaction layer 140 within the nonirradiated region 110. The critical dimension, CD, or the image of the photoresist is shrunk during the processes of the present invention. Furthermore, the processes of the first embodiment may be performed in the in-situ environment.

Even if the photoresist layer 105 is a positive photoresist in the first embodiment of the present invention, the photoresist layer 105 of the present invention is not limited in positive photoresist. The first chemical material within the photoresist layer 105, i.e. the irradiated region 105′, may be an acid-based material. The first chemical material within the irradiated region 105′ and the second chemical material within the chemical diffusion layer 120 may be the same. The nonirradiated region 110 and the irradiated region 105′ may be formed in a photolithography process.

The difference between the first line width D1, i.e. the original line width, and the second line width D2, i.e. the shrinking line width, is the diffusive depth d of the chemical reaction layer 140 within the nonirradiated region 110. The diffusive depth d of the chemical reaction layer 140 depends on the diffusive rate of the first chemical material. The baking process controls the diffusive depth of the chemical diffusion layer 140 by the time for baking. The baking process lasts more than 10 seconds and less than 600 seconds. For example, the baking process lasts about 10 seconds to 300 seconds, 10 seconds to 170 seconds, 70 seconds to 450 seconds or 70 seconds to 150 seconds. The baking process could also control the diffusive depth of the chemical diffusion layer 140 by temperature. The baking temperature in the baking is higher than 50 degrees centigrade and lower than 200 degrees centigrade. The temperature in the baking process may last about 90 degrees centigrade to 200 degrees centigrade, 90 degrees centigrade to 150 degrees centigrade, 80 degrees centigrade to 160 degrees centigrade or 50 degrees centigrade to 150 degrees centigrade.

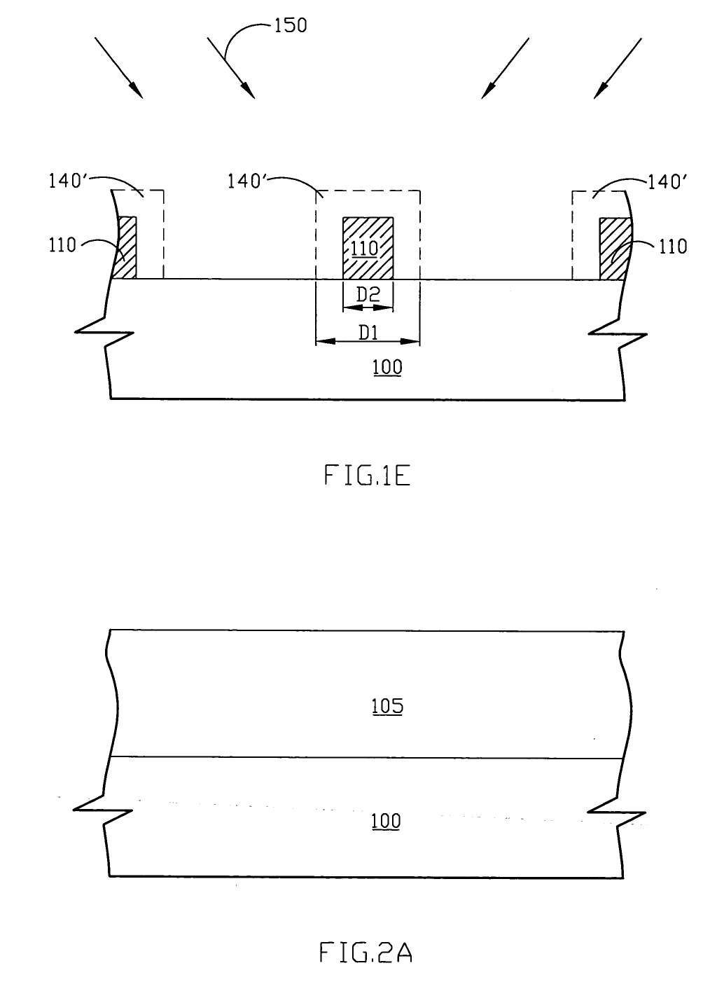

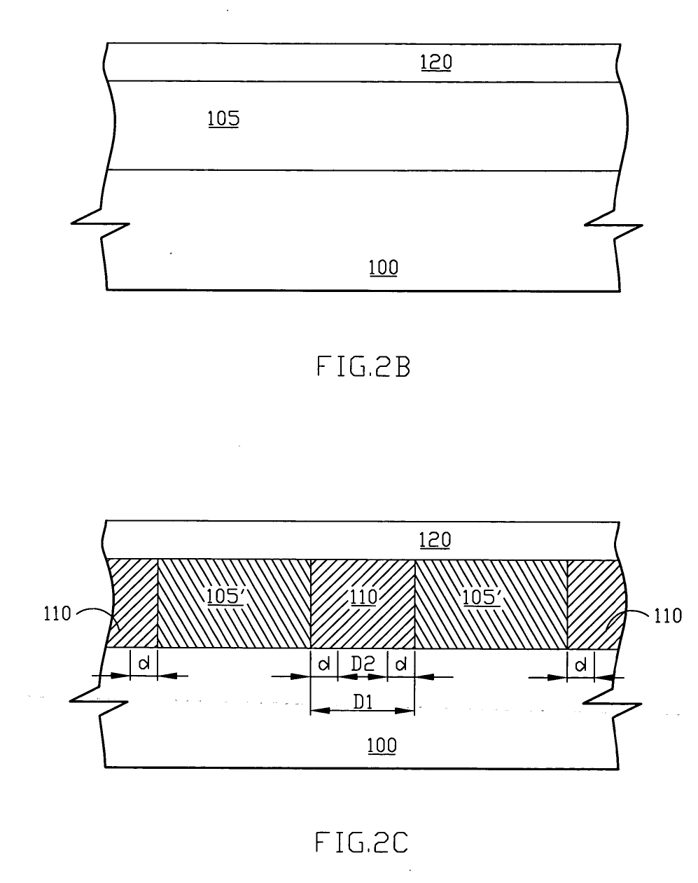

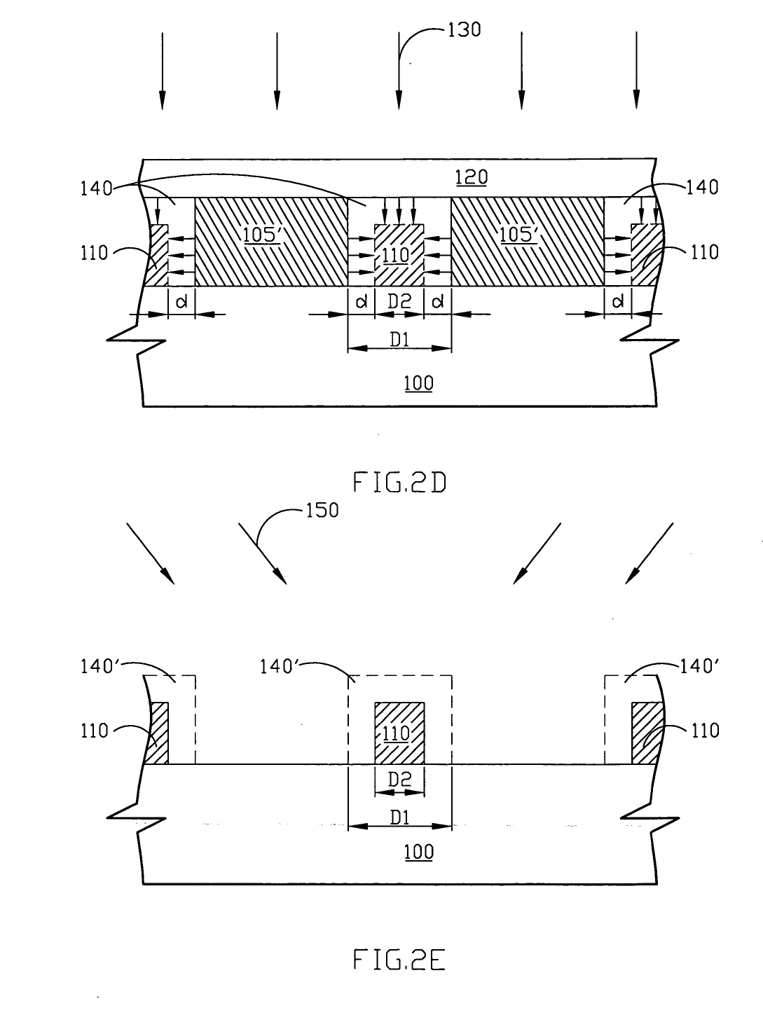

As illustrated in FIG. 2A, the second embodiment of the present invention provides a substrate 100 at first and then apply a photoresist layer 105 on the substrate 100. Then a chemical diffusion layer 120 including a second chemical material is formed on the photoresist layer 105, as shown in FIG. 2B. As shown in FIG. 2C, the photoresist layer 105 is exposed to form a nonirradiated region 110 and an irradiated region 105′ including a first chemical material, as the first embodiment. As shown in FIG. 2D, the first chemical material within the irradiated region 105′ and the second chemical material within the chemical diffusion layer 120 is diffused into the nonirradiated region 110 in a baking process 130. Afterward, a chemical reaction layer 140 with a diffusive depth d is formed within the nonirradiated region 110. Subsequently, the chemical diffusion layer 120, the irradiated region 105′ and the chemical reaction layer 140 is removed by developer in a developing process 150 to form a second line width D2 of the nonirradiated region 110, as shown in FIG. 2E. The difference between the first line width D1 and the second line width D2 is the diffusive depth d of the chemical diffusion layer 120 within the nonirradiated region 110. The critical dimension, CD, or the image of the photoresist is shrunk during the processes of the present invention.

The nonirradiated region 110 and the irradiated region 105′ of the first embodiment of the present invention is formed before the chemical diffusion layer 120 formed on the photoresist layer 105. The nonirradiated region 110 and the irradiated region 105′ of the second embodiment is formed after the chemical diffusion layer 120 formed on the photoresist layer 105 because the chemical diffusion layer 120 is transparent.

As discussed above, the present invention shrinks the critical dimension or the image by providing chemical material to react with the photoresist, i.e. the first photoresist region in a baking process. The developing process for removing the chemical diffusion layer, the second photoresist region and the chemical reaction layer within the first photoresist region at the same time reduces the amount of the whole processes to shrink the critical dimension or the image. Therefore, the present invention provides the advantages such as less complication, lower cost, easier control ability of shrinking the CD, the improved line edge, less film loses, more enlarged process window and less amount of the whole processes. Accordantly, the control window of the critical dimension or the image bias becomes wider and wider. Therefore, the present invention is appropriate for deep sub-micron technology in providing semiconductor devices.

Of course, the present invention is possible to apply to the process for shrinking the line width of different photoresist, and it is also possible to be applied to any process for controlling the critical dimension or the image in the semiconductor process. Furthermore, at the present time, the method of the present invention that utilizes the acid-process and baking process to control the line width of the photoresist has not been applied to concerning shrinking the critical dimension or the image of the photoresist. The method of the present invention is the best process for trimming the photoresist compatible process for deep sub-micron process.

Obviously, many modifications and variations of the present invention are possible in light of the above teachings. It is to be understood that within the scope of the appended claims, the present invention may be practiced other than as specifically described herein.

Although the specific embodiments have been illustrated and described, it will be obvious to those skilled in the art that various modifications may be made without departing from what is intended to be limited solely by the appended claims.

What is claimed is:

1. A method for shrinking the image of photoresist, the method comprising:
providing a substrate;
forming a photoresist layer on said substrate;
exposing said photoresist layer to form a first photoresist region and a second photoresist region;
forming a chemical diffusion layer on said first photoresist region and said second photoresist region;
baking said chemical diffusion layer, said first photoresist region and said second photoresist region; and
developing said chemical diffusion layer, said first photoresist region and said second photoresist region.

2. The method according to claim 1, wherein said second photoresist region includes a first chemical material.

3. The method according to claim 2, wherein said first chemical material is an acid-based material.

4. The method according to claim 2, wherein said first chemical material comprises a fluorine-base acid.

5. The method according to claim 2, wherein said chemical diffusion layer including a second chemical material.

6. The method according to claim 5, wherein said first chemical material and said second chemical material is the same.

7. The method according to claim 5, wherein said first chemical material of said second photoresist region and said second chemical material of said chemical diffusion layer is diffused into said first photoresist region to react with the material of said first photoresist region for forming a chemical reaction layer within said first photoresist region in said baking process.

8. The method according to claim 7, wherein said first photoresist region shrinks in line width in said developing process.

9. The method according to claim 8, wherein said shrinking line width of said first photoresist region depends on a diffusive rate of said first chemical material.

10. The method according to claim 9, wherein said shrinking line width of said first photoresist region is controlled by the time for baking.

11. The method according to claim 10, wherein said baking process lasts about 10 seconds to 600 seconds.

12. The method according to claim 9, wherein said shrinking line width of said first photoresist region is controlled by temperature.

13. The method according to claim 12, wherein the temperature in said baking process lasts about 50 degrees centigrade to 200 degrees centigrade.

14. A method for shrinking the image of photoresist, the method comprising:
providing a substrate; F
forming a photoresist layer on said substrate; F
forming a chemical diffusion layer on said photoresist layer;
exposing said photoresist layer to form a first photoresist region and a second photoresist region;
baking said chemical diffusion layer, said first photoresist region and said second photoresist region; and
developing said chemical diffusion layer, said first photoresist region and said second photoresist region.

15. The method according to claim 14, wherein said chemical diffusion layer is transparent.

16. The method according to claim 14, wherein said second photoresist region includes a first chemical material.

17. The method according to claim 16, wherein said chemical diffusion layer including a second chemical material.

18. The method according to claim 17, wherein said first chemical material of said second photoresist region and said second chemical material of said chemical diffusion layer is diffused into said first photoresist region to react with the material of said first photoresist region for forming a chemical reaction layer within said first photoresist region in said baking process.

19. The method according to claim 18, wherein said first photoresist region shrinks in line width in said developing process.

20. The method according to claim 19, wherein said shrinking line width of said first photoresist region depends on a diffusive rate of said first chemical material.
